(19) United States
(12) Patent Application Publication
(10) Pub. No.: US 2024/0332072 A1
(43) Pub. Date: Oct. 3, 2024

(54) PROTECTIVE CAPPING LAYER FOR AREA SELECTIVE DEPOSITION

(71) Applicant: Applied Materials, Inc., Santa Clara, CA (US)

(72) Inventor: Andrea Leoncini, Singapore (SG)

(73) Assignee: Applied Materials, Inc., Santa Clara, CA (US)

(21) Appl. No.: 18/613,998

(22) Filed: Mar. 22, 2024

Related U.S. Application Data
(60) Provisional application No. 63/456,137, filed on Mar. 31, 2023.

(51) Int. Cl. H01L 21/768; C23C 16/455; H01L 21/285

(52) U.S. Cl. CPC H01L 21/76834; C23C 16/45527; C23C 16/45553; H01L 21/28568

(57) ABSTRACT

Described are methods of forming a protective capping layer on a metal layer of a semiconductor substrate. A metal layer is deposited using a metal precursor and a reactant pulsed to form the metal layer having a reactive surface. The number of cycles can be in a range of from 1 to 10 cycles or from 2 to 5 cycles or from 2 to 100 cycles. The metal layer is then exposed to a long chain precursor (e.g., primary amines, alcohols, thiols, phosphines, selenols) and a metal precursor to form a protective capping layer on the metal layer. The number of cycles can be in a range of from 1 to 10 cycles or from 2 to 5 cycles, depending upon the desired thickness of the protective capping layer.

### CROSS-REFERENCE TO RELATED APPLICATIONS

This application claims priority to U.S. Provisional Application No. 63/456,137, filed Mar. 31, 2023, the entire disclosure of which is hereby incorporated by reference herein.

### TECHNICAL FIELD

Embodiments of the disclosure relate to methods for forming a protective capping layer on a metal layer so that area selective deposition (ASD) can be performed. In particular, embodiments of the disclosure are directed to methods of depositing a protective capping layer at the end of the atomic layer deposition (ALD) of the film it protects.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The semiconductor industry faces many challenges in the pursuit of device miniaturization which involves rapid scaling of nanoscale features. Such issues include the introduction of complex fabrication steps such as multiple lithography steps and integration of high-performance materials. Traditional spacer fabrication processes include conformal film deposition on 3D structures (e.g., fins, mandrel, and the like) followed by directional plasma dry etching to remove the top and bottom layer while keeping the sidewall film as a spacer. However, it has been found that the dry etch process could insidiously damage the sidewall surface and change the film properties; eventually affecting device performance and yield.

To maintain the cadence of device miniaturization, selective deposition has shown promise as it has the potential to remove costly lithographic steps by simplifying integration schemes.

Selective deposition of materials can be accomplished in a variety of ways. A chemical precursor may react selectively with one surface relative to another surface (metallic or dielectric). Process parameters such as pressure, substrate temperature, precursor partial pressures, and/or gas flows might be modulated to modulate the chemical kinetics of a particular surface reaction. Another possible scheme involves surface pretreatments that can be used to activate or deactivate a surface of interest to an incoming film deposition precursor.

Area-selective atomic layer deposition (AS-ALD) can be used for selective deposition of material. During AS-ALD, SAM deposition on nitrides, oxides, and silicides requires the development of a molecule able to bind selectively to the surface of the formed layer with high surface coverage. In many cases this requires cleaning or pre-treatment of the surfaces. Selectivity is often challenging when more films are exposed. There is an ongoing need in the art, therefore, for methods to improve deposition selectivity and to avoid the problems encountered during AS-ALD.

### SUMMARY

One or more embodiments of the disclosure are directed to a method of forming a semiconductor film. In one or more embodiments, the method comprises forming a metal layer on a substrate surface by exposing the substrate surface to a metal precursor and a reactant, the metal layer having a reactive surface; and forming a protective capping layer on the metal layer by exposing the metal layer to the metal precursor and a second precursor, the second precursor comprising a functional group and a carbon chain having from 2 to 20 carbon atoms, the functional group selected from the group consisting of a primary amine, a thiol, a phosphine, an alcohol, and a selenol.

Additional embodiments of the disclosure are directed to a method of forming a semiconductor film. In one or more embodiments, the method comprises: performing a first process cycle comprising exposing a substrate surface to a metal precursor and a reactant to form a metal layer on the substrate surface, the metal layer having a reactive surface; and performing a second process cycle comprising exposing the metal layer to the metal precursor and a second precursor to form a protective capping layer on the metal layer, the second precursor comprising a carbon chain having from 2 to 20 carbon atoms and a functional group, the functional group selected from the group consisting of a primary amine, a thiol, a phosphine, an alcohol, and a selenol.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method according to one or more embodiments; and

FIG. 2 illustrates a cross-section view of a substrate being processed according to one or more embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm or 300 mm diameter wafers, as well as rectangular or square panes. In some embodiments, the substrate comprises a rigid discrete material.

The term “on” indicates that there is direct contact between elements. The term “directly on” indicates that there is direct contact between elements with no intervening elements.

According to one or more embodiments, the method uses an atomic layer deposition (ALD) process to form a metal layer on a substrate surface, followed by formation of a protective capping layer on the metal layer. In such embodiments, the substrate surface is exposed to precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used in this specification and the appended claims, the terms “reactive compound”, “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition). The substrate, or portion of the substrate, is exposed sequentially to the two or more reactive compounds which are introduced into a reaction zone of a processing chamber.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In some embodiments, there may be two reactants, A and B, which are alternatingly pulsed and purged. In other embodiments, there may be three or more reactants, A, B, and C, which are alternatingly pulsed and purged.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In one or more embodiments, a strong protective film for area selective deposition (ASD) which is deposited as the last stage of the atomic layer deposition (ALD) of the layer it is meant to protect is formed. A suitable precursor, e.g., a long-chain amine or alcohol, is used in the last 1-5 cycles of an ALD process instead of NH₃ or H₂O. This results in a protective layer, like a SAM, but that is strongly bound to the surface and has high coverage.

In one or more embodiments, a strongly bound SAM-like protective layer, i.e., protective capping layer, is deposited at the end of the ALD of the film it protects, taking advantage of the reactivity of the ALD precursors. The film requires harsher conditions than a regular SAM to be removed, allowing for the protective film to withstand a wider range of process conditions, and to be used in conjunction with other processes using SAMs.

In one or more embodiments, a metal layer is deposited using a metal precursor and a reactant pulsed to form the metal layer having a reactive surface. The number of cycles is ideally one but can be in a range of from 1 to 10 cycles or from 2 to 5 cycles or from 2 to 100 cycles. In one or more embodiments, the metal layer is then exposed to a long chain precursor (e.g., primary amines, alcohols, thiols, phosphines, selenols) and the metal precursor to form a protective capping layer on the metal layer. The number of cycles again is ideally one but can be in a range of from 1 to 10 cycles or from 2 to 5 cycles, depending upon the desired thickness of the protective capping layer.

The embodiments of the disclosure are described by way of the Figures, which illustrate devices (e.g., transistors) and processes for forming semiconductor structures in accordance with one or more embodiments of the disclosure. The processes shown are merely illustrative possible uses for the disclosed processes, and the skilled artisan will recognize that the disclosed processes are not limited to the illustrated applications.

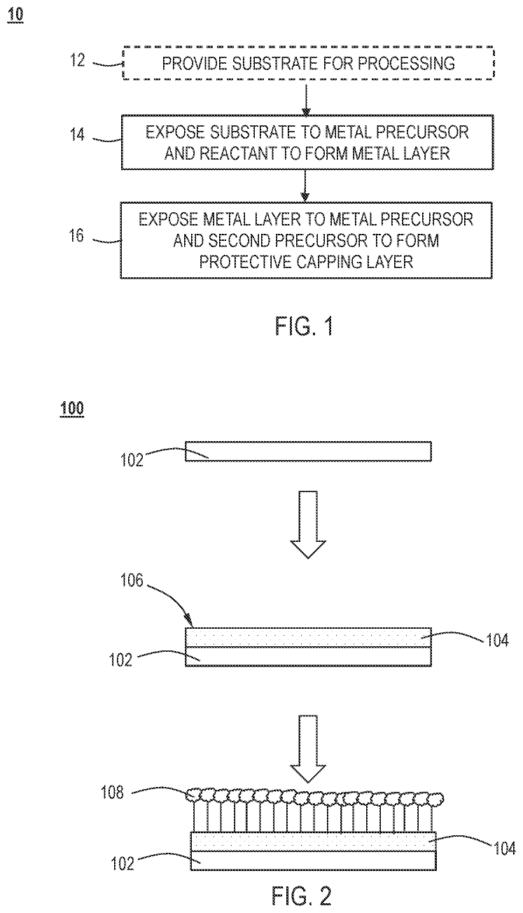

FIG. 1 illustrates a process flow diagram of a method 10 according to one or more embodiments. FIG. 2 illustrates cross-sectional views of a semiconductor substrate 100 being processed according to the method of one or more embodiments. Referring to FIGS. 1 and 2, in one or more embodiments, at operation 12, a substrate 102 is provided. As used in this specification and the appended claims, the term “provided” means that the substrate 102 is made available for processing (e.g., positioned in a processing chamber).

With reference to FIG. 2, in one or more embodiments, the substrate 102 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

Referring to FIGS. 1 and 2, at operation 14, the substrate 102 is exposed to a metal precursor and a reactant to form a metal layer 104 on the substrate surface. The metal layer 104 has a reactive surface 106. The metal layer 104 can be any suitable material known to the skilled artisan. In one or more embodiments, the metal layer 104 is one or more of a metal nitride, a metal oxide, a metal sulfide, a metal phosphide, and a metal selenide.

In one or more embodiments, the reactant used to form the metal layer 104 can be any suitable reactant known to the skilled artisan. In one or more embodiments, the reactant comprises one or more of ammonia (NH₃), water (H₂O), hydrogen sulfide (H₂S), phosphine (PH₃), ozone (O₃), hydrogen peroxide (H₂O₂), nitrous oxide (N₂O), and hydrogen selenide (H₂Se).

In one or more embodiments, the metal precursor that reacts with the reactant to form the metal layer 104, comprises a metal and a reactive species. In one or more embodiments, the reactive species is any suitable reactive species. In some embodiments, the reactive species is selected from the group consisting of halide, alkyl, arene, cyclopentadienyl, alkyne, diene, diketonate, amido, imido, alkoxo, oxo, carbonyl, amidinate, guanidinate, and formamidinate.

In one or more embodiments, the metal of the metal precursor may be any suitable transition metal. In one or more embodiments, the metal of the metal precursor is selected from one or more of titanium (Ti), silicon (Si), molybdenum (Mo), hafnium (Hf), zirconium (Zr), aluminum (Al), antimony (Sb), boron (B), gallium (Ga), germanium (Ge), indium (In), niobium (Nb), rhenium (Re), tantalum (Ta), tin (Sn), tungsten (W), and zinc (Zn).

In one or more embodiments, the metal precursor used to form the metal layer 104 can be any suitable metal precursor known to the skilled artisan. The metal precursor may be any inorganic or organometallic precursor. The method of one or more embodiments is generally applicable to most binary and/or ternary metal films.

In one or more embodiments, the metal precursor used to form the metal layer 104 may be any suitable metal precursor known to the skilled artisan. In one or more embodiments, the metal precursor comprises one or more of, aluminum chloride, aluminum bromide, aluminum iodide, boron trichloride, boron tribromide, gallium trichloride, germanium tetrachloride, antimony trichloride, antimony pentachloride, indium trichloride, silicon tetrachloride, silicon tetrabromide, silicon tetraiodide, hexachlorodisilane, titanium tetrachloride, titanium tetrabromide, titanium tetraiodide, zirconium tetrachloride, hafnium tetrachloride, niobium pentachloride, niobium pentabromide, tantalum pentachloride, tantalum pentabromide, molybdenum pentachloride, tungsten hexachloride, rhenium pentachloride, zinc chloride, tin chloride, trimethyl aluminum, tetrakis (dimethylamido) titanium, tetrakis (dimethylamido) zirconium, tetrakis (dimethylamido) hafnium, (t-butylimido) tris (diethylamino) niobium, (t-butylimido) tris (diethylamino) tantalum, pentakis (dimethylamido) tantalum, bis (ethylbenzene) molybdenum, molybdenum hexacarbonyl, tungsten hexacarbonyl, and diethylzinc.

Referring to FIGS. 1 and 2, at operation 16, the metal layer 104 having the reactive surface 106 is exposed to a metal precursor and a second precursor to form a protective capping layer 108. The protective capping layer 108 may have any suitable thickness. In one or more embodiments, the protective capping layer 108 has a thickness in a range of from 0.5 nm to 5 nm.

The second precursor can be any suitable precursor known to the skilled artisan. In one or more embodiments, the second precursor comprises a function group and a carbon chain having from 2 to 20 carbon atoms. In one or more embodiments, the functional group is selected from the group consisting of a primary amine, a thiol, a phosphine, an alcohol, and a selenol.

In one or more embodiments, the second comprises one or more of a compound selected from

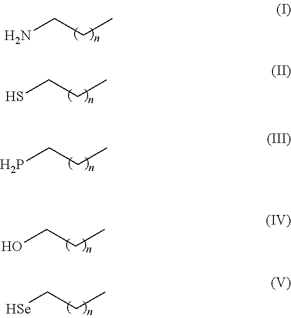

wherein n is an integer in a range of from 1 to 20.

In one or more embodiments, the second precursor reacts with a metal precursor to form the protective capping layer 108 on the metal layer 104. In one or more embodiments, the metal precursor may be the same metal precursor as that used to form the metal layer 104. In other embodiments, the metal precursor used to the form the protective capping layer 108 is different from the metal precursor used to form the metal layer 104.

In one or more embodiments, the metal of the metal precursor may be any suitable transition metal. In one or more embodiments, the metal of the metal precursor is selected from one or more of titanium (Ti), silicon (Si), molybdenum (Mo), hafnium (Hf), zirconium (Zr), aluminum (Al), antimony (Sb), boron (B), gallium (Ga), germanium (Ge), indium (In), niobium (Nb), rhenium (Re), tantalum (Ta), tin (Sn), tungsten (W), and zinc (Zn).

In one or more embodiments, the metal precursor used to react with the second precursor to form the protective capping layer 108 can be any suitable metal precursor known to the skilled artisan. The metal precursor may be any inorganic or organometallic precursor. The method of one or more embodiments is generally applicable to most binary and/or ternary metal films.

In one or more embodiments, the metal precursor used to form protective capping layer 108 may be any suitable metal precursor known to the skilled artisan. In one or more embodiments, the metal precursor comprises one or more of, aluminum chloride, aluminum bromide, aluminum iodide, boron trichloride, boron tribromide, gallium trichloride, germanium tetrachloride, antimony trichloride, antimony pentachloride, indium trichloride, silicon tetrachloride, silicon tetrabromide, silicon tetraiodide, hexachlorodisilane, titanium tetrachloride, titanium tetrabromide, titanium tetraiodide, zirconium tetrachloride, hafnium tetrachloride, niobium pentachloride, niobium pentabromide, tantalum pentachloride, tantalum pentabromide, molybdenum pentachloride, tungsten hexachloride, rhenium pentachloride, zinc chloride, tin chloride, trimethyl aluminum, tetrakis (dimethylamido) titanium, tetrakis (dimethylamido) zirconium, tetrakis (dimethylamido) hafnium, (t-butylimido) tris (diethylamino) niobium, (t-butylimido) tris (diethylamino) tantalum, pentakis (dimethylamido) tantalum, bis (ethylbenzene) molybdenum, molybdenum hexacarbonyl, tungsten hexacarbonyl, and diethylzinc.

In other embodiments, the method of forming a semiconductor film involves performing a first process cycle and a second process cycle to form a protective capping layer 108 on a metal layer 104 on a substrate. The metal layer 104 can be any suitable material known to the skilled artisan. In one or more embodiments, the metal layer 104 is one or more of a metal nitride, a metal oxide, a metal sulfide, a metal sulfide, a metal sulfide, a metal sulfide, and a metal selenide.

In one or more embodiments, in the first process cycle, the substrate 102 is exposed to a metal precursor and a reactant to form a metal layer 104 on the substrate surface. The metal layer 104 has a reactive surface 106. In one or more embodiments, the metal layer 104 comprises one or more of a metal nitride, a metal oxide, a metal sulfide, a metal phosphide, and a metal selenide.

In one or more embodiments, the reactant used to form the metal layer 104 can be any suitable reactant known to the skilled artisan. In one or more embodiments, the reactant comprises one or more of ammonia (NH₃), water (H₂O), hydrogen sulfide (H₂S), phosphine (PH₃), ozone (O₃), hydrogen peroxide (H₂O₂), nitrous oxide (N₂O), and hydrogen selenide (H₂Se).

In one or more embodiments, the metal precursor that reacts with the reactant to form the metal layer 104, comprises a metal and a reactive species. In one or more embodiments, the reactive species is any suitable reactive species. In some embodiments, the reactive species is selected from the group consisting of halide, alkyl, arene, cyclopentadienyl, alkyne, diene, diketonate, amido, imido, alkoxo, oxo, carbonyl, amidinate, guanidinate, and formamidinate.

In one or more embodiments, the metal of the metal precursor may be any suitable transition metal. In one or more embodiments, the metal of the metal precursor is selected from one or more of titanium (Ti), silicon (Si), molybdenum (Mo), hafnium (Hf), zirconium (Zr), aluminum (Al), antimony (Sb), boron (B), gallium (Ga), germanium (Ge), indium (In), niobium (Nb), rhenium (Re), tantalum (Ta), tin (Sn), tungsten (W), and zinc (Zn).

The metal precursor used to form the metal layer 104 can be any suitable metal precursor known to the skilled artisan. The metal precursor may be any inorganic or organometallic precursor. The method of one or more embodiments is generally applicable to most binary and/or ternary metal films.

In one or more embodiments, the metal precursor used to form the metal layer 104 may be any suitable metal precursor known to the skilled artisan. In one or more embodiments, the metal precursor comprises one or more of, aluminum chloride, aluminum bromide, aluminum iodide, boron trichloride, boron tribromide, gallium trichloride, germanium tetrachloride, antimony trichloride, antimony pentachloride, indium trichloride, silicon tetrachloride, silicon tetrabromide, silicon tetraiodide, hexachlorodisilane, titanium tetrachloride, titanium tetrabromide, titanium tetraiodide, zirconium tetrachloride, hafnium tetrachloride, niobium pentachloride, niobium pentabromide, tantalum pentachloride, tantalum pentabromide, molybdenum pentachloride, tungsten hexachloride, rhenium pentachloride, zinc chloride, tin chloride, trimethyl aluminum, tetrakis (dimethylamido) titanium, tetrakis (dimethylamido) zirconium, tetrakis (dimethylamido) hafnium, (t-butylimido) tris (diethylamino) niobium, (t-butylimido) tris (diethylamino) tantalum, pentakis (dimethylamido) tantalum, bis (ethylbenzene) molybdenum, molybdenum hexacarbonyl, tungsten hexacarbonyl, and diethylzinc.

The first process cycle can be repeated any number of times depending upon the desired thickness of the metal layer 104. In one or more embodiments, the first process cycle is repeated from 2 to 200 times, or from 2 to 100 times, or from 2 to 50 times.

In one or more embodiments, in the second process cycle, the metal layer 104 having the reactive surface 106 is exposed to a metal precursor and a second precursor to form a protective capping layer 108 on the metal layer 104. The protective capping layer 108 may have any suitable thickness. In one or more embodiments, the protective capping layer 108 has a thickness in a range of from 0.5 nm to 5 nm.

The second precursor can be any suitable precursor known to the skilled artisan. In one or more embodiments, the second precursor comprises a function group and a carbon chain having from 2 to 20 carbon atoms. In one or more embodiments, the functional group is selected from the group consisting of a primary amine, a thiol, a phosphine, an alcohol, and a selenol.

In one or more embodiments, the second comprises one or more of a compound selected from

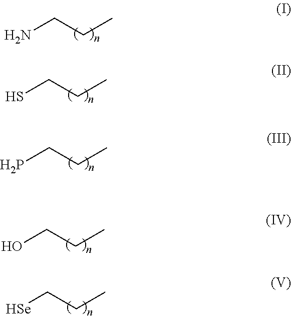

wherein n is an integer in a range of from 1 to 20.

In one or more embodiments, the second precursor reacts with any suitable metal precursor known to the skilled artisan. In one or more embodiments, the metal precursor may be the same metal precursor as that used to form the metal layer 104. In other embodiments, the metal precursor used to the form the protective capping layer 108 is different from the metal precursor used to form the metal layer 104.

In one or more embodiments, the metal of the metal precursor may be any suitable transition metal. In one or more embodiments, the metal of the metal precursor is selected from one or more of titanium (Ti), silicon (Si), molybdenum (Mo), hafnium (Hf), zirconium (Zr), aluminum (Al), antimony (Sb), boron (B), gallium (Ga), germanium (Ge), indium (In), niobium (Nb), rhenium (Re), tantalum (Ta), tin (Sn), tungsten (W), and zinc (Zn).

In one or more embodiments, the metal precursor used to react with the second precursor to form the protective capping layer 108 can be any suitable metal precursor known to the skilled artisan. The metal precursor may be any inorganic or organometallic precursor. The method of one or more embodiments is generally applicable to most binary and/or ternary metal films.

In one or more embodiments, the metal precursor used to form protective capping layer 108 may be any suitable metal precursor known to the skilled artisan. In one or more embodiments, the metal precursor comprises one or more of, aluminum chloride, aluminum bromide, aluminum iodide, boron trichloride, boron tribromide, gallium trichloride, germanium tetrachloride, antimony trichloride, antimony pentachloride, indium trichloride, silicon tetrachloride, silicon tetrabromide, silicon tetraiodide, hexachlorodisilane, titanium tetrachloride, titanium tetrabromide, titanium tetraiodide, zirconium tetrachloride, hafnium tetrachloride, niobium pentachloride, niobium pentabromide, tantalum pentachloride, tantalum pentabromide, molybdenum pentachloride, tungsten hexachloride, rhenium pentachloride, zinc chloride, tin chloride, trimethyl aluminum, tetrakis (dimethylamido) titanium, tetrakis (dimethylamido) zirconium, tetrakis (dimethylamido) hafnium, (t-butylimido) tris (diethylamino) niobium, (t-butylimido) tris (diethylamino) tantalum, pentakis (dimethylamido) tantalum, bis (ethylbenzene) molybdenum, molybdenum hexacarbonyl, tungsten hexacarbonyl, and diethylzinc.

The second process cycle can be repeated any number of times depending upon the desired thickness of the protective capping layer 108. In one or more embodiments, the second process cycle is repeated from 2 to 20 times, or from 2 to 10 times, or from 2 to 5 times.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor film, the method comprising:
form a metal layer on a substrate surface by exposing the substrate surface to a metal precursor and a reactant, the metal layer having a reactive surface; and
form a protective capping layer on the metal layer by exposing the metal layer to a second metal precursor and a second precursor, the second precursor comprising a functional group and a carbon chain having from 2 to 20 carbon atoms, the functional group selected from the group consisting of a primary amine, a thiol, a phosphine, an alcohol, and a selenol.

2. The method of claim 1, wherein the reactant comprises one or more of ammonia (NH₃), water (H₂O), hydrogen sulfide (H₂S), phosphine (PH₃), ozone (O₃), hydrogen peroxide (H₂O₂), nitrous oxide (N₂O), and hydrogen selenide (H₂Se).

3. The method of claim 1, wherein the metal precursor and the second metal precursor independently comprise a metal and a reactive species.

4. The method of claim 3, wherein the metal is a transition metal.

5. The method of claim 4, wherein the metal is selected from one or more of titanium (Ti), silicon (Si), molybdenum (Mo), hafnium (Hf), zirconium (Zr), aluminum (Al), antimony (Sb), boron (B), gallium (Ga), germanium (Ge), indium (In), niobium (Nb), rhenium (Re), tantalum (Ta), tin (Sn), tungsten (W), and zinc (Zn).

6. The method of claim 3, wherein the reactive species is selected from the group consisting of halide, alkyl, arene, cyclopentadienyl, alkyne, diene, diketonate, amido, imido, alkoxo, oxo, carbonyl, amidinate, guanidinate, and formamidinate.

7. The method of claim 2, wherein the metal precursor and the second metal precursor independently comprise one or more of, aluminum chloride, aluminum bromide, aluminum iodide, boron trichloride, boron tribromide, gallium trichloride, germanium tetrachloride, antimony trichloride, antimony pentachloride, indium trichloride, silicon tetrachloride, silicon tetrabromide, silicon tetraiodide, hexachlorodisilane, titanium tetrachloride, titanium tetrabromide, titanium tetraiodide, zirconium tetrachloride, hafnium tetrachloride, niobium pentachloride, niobium pentabromide, tantalum pentachloride, tantalum pentabromide, molybdenum pentachloride, tungsten hexachloride, rhenium pentachloride, zinc chloride, tin chloride, trimethyl aluminum, tetrakis (dimethylamido) titanium, tetrakis (dimethylamido) zirconium, tetrakis (dimethylamido) hafnium, (t-butylimido) tris (diethylamino) niobium, (t-butylimido) tris (diethylamino) tantalum, pentakis (dimethylamido) tantalum, bis (ethylbenzene) molybdenum, molybdenum hexacarbonyl, tungsten hexacarbonyl, and diethylzinc.

8. The method of claim 1, wherein the metal layer comprises one or more of a metal nitride, a metal oxide, a metal sulfide, a metal phosphide, and a metal selenide.

9. The method of claim 1, wherein the protective capping layer has a thickness in a range of from 0.5 nm to 5 nm.

10. The method of claim 1, wherein the second precursor comprises one or more of a compound selected from 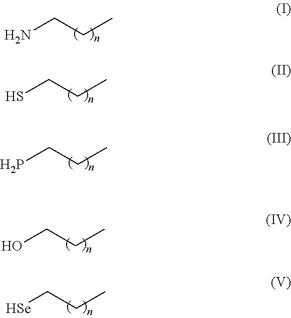
wherein n is an integer in a range of from 1 to 20.

11. A method of forming a semiconductor film, the method comprising:
performing a first process cycle comprising exposing a substrate surface to a metal precursor and a reactant to form a metal layer on the substrate surface, the metal layer having a reactive surface; and
performing a second process cycle comprising exposing the metal layer to a second metal precursor and a second precursor to form a protective capping layer on the metal layer, the second precursor comprising a carbon chain having from 2 to 20 carbon atoms and a functional group, the functional group selected from the group consisting of a primary amine, a thiol, a phosphine, an alcohol, and a selenol.

12. The method of claim 11, wherein the metal precursor and the second metal precursor independently comprise a metal and a reactive species and wherein the reactant comprises one or more of ammonia (NH₃), water (H₂O), hydrogen sulfide (Hs), phosphine (PH₃), ozone (O₃), hydrogen peroxide (H₂O₂), nitrous oxide (N₂O), and hydrogen selenide (H₂Se).

13. The method of claim 12, wherein the metal is selected from one or more of titanium (Ti), silicon (Si), molybdenum (Mo), hafnium (Hf), zirconium (Zr), aluminum (Al), antimony (Sb), boron (B), gallium (Ga), germanium (Ge), indium (In), niobium (Nb), rhenium (Re), tantalum (Ta), tin (Sn), tungsten (W), and zinc (Zn).

14. The method of claim 12, wherein the reactive species is selected from the group consisting of halide, alkyl, arene, cyclopentadienyl, alkyne, diene, diketonate, amido, imido, alkoxo, oxo, carbonyl, amidinate, guanidinate, and formamidinate.

15. The method of claim 12, wherein the metal precursor and the second metal precursor independently comprise one or more of aluminum chloride, aluminum bromide, aluminum iodide, boron trichloride, boron tribromide, gallium trichloride, germanium tetrachloride, antimony trichloride, antimony pentachloride, indium trichloride, silicon tetrachloride, silicon tetrabromide, silicon tetraiodide, hexachlorodisilane, titanium tetrachloride, titanium tetrabromide, titanium tetraiodide, zirconium tetrachloride, hafnium tetrachloride, niobium pentachloride, niobium pentabromide, tantalum pentachloride, tantalum pentabromide, molybdenum pentachloride, tungsten hexachloride, rhenium pentachloride, zinc chloride, tin chloride, trimethyl aluminum, tetrakis (dimethylamido) titanium, tetrakis (dimethylamido) zirconium, tetrakis (dimethylamido) hafnium, (t-butylimido) tris (diethylamino) niobium, (t-butylimido) tris (diethylamino) tantalum, pentakis (dimethylamido) tantalum, bis (ethylbenzene) molybdenum, molybdenum hexacarbonyl, tungsten hexacarbonyl, and diethylzinc.

16. The method of claim 11, wherein the metal layer comprises one or more of a metal nitride, a metal oxide, a metal sulfide, a metal phosphide, and a metal selenide.

17. The method of claim 11, wherein the protective capping layer has a thickness in a range of from 0.5 nm to 5 nm.

18. The method of claim 11, wherein the second precursor comprises one or more of a compound selected from 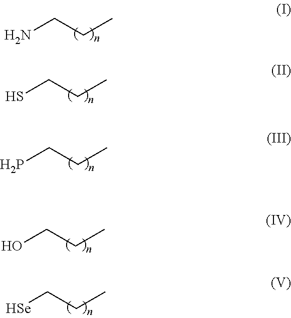
wherein n is an integer in a range of from 1 to 20.

19. The method of claim 11, wherein the first process cycle is repeated from 2 to 100 times.

20. The method of claim 11, wherein the second process cycle is repeated from 2 to 10 times.
